(19) United States
(12) Patent Application Publication
(10) Pub. No.: US 2012/0038939 A1
(43) Pub. Date: Feb. 16, 2012

(54) COLOR CORRECTION PROCESSING APPARATUS AND COLOR CORRECTION PROCESSING METHOD

(75) Inventor: Naofumi Yamamoto, Kanagawa-ken (JP)

(73) Assignees: TOSHIBA TEC KABUSHIKI KAISHA, Tokyo (JP); KABUSHIKI KAISHA TOSHIBA, Tokyo (JP)

(21) Appl. No.: 13/205,946

(22) Filed: Aug. 9, 2011

Related U.S. Application Data
(60) Provisional application No. 61/372,667, filed on Aug. 11, 2010.

(51) Int. Cl. H04N 1/60; G03F 3/08

(52) U.S. Cl. 358/1.9; 358/518

(57) ABSTRACT

According to one embodiment, each color correction processing apparatus includes an input portion, a storing portion and a correction portion. The input portion inputs each image signal value corresponding to each color component for each recording head block in order to record a color image by a plurality of recording head blocks. The storing portion records reference color deviation amount data that shows a plurality of reference color deviation amounts corresponding to a plurality of reference color points for each recording head block. The correction portion corrects each image signal value on the basis of the reference color deviation amount data. Furthermore, the correction portion corrects a correction target image signal value corresponding to non-reference color points shifted from the reference color points by the interpolation on the basis of the reference color deviation amount data.

### CROSS-REFERENCE TO RELATED APPLICATIONS

This application is based upon and claims the benefit of priority from U.S. Provisional Application No. 61/372,667, filed on Aug. 11, 2010; the entire contents of which are incorporated herein by reference.

### FIELD

Embodiments described herein relate generally to a color correction processing apparatus and a color correction processing method.

### BACKGROUND

A color recording apparatus configured of a plurality of recording head blocks is widely known. The color recording apparatus includes a drum that affixes and rotates paper sheets and further includes a plurality of recording head blocks which is juxtaposed in the rotation direction of the drum. Each recording head block includes nozzle rows (nozzle plates) which correspond to each color and discharge each color of ink. Each nozzle row includes a plurality of ink discharging nozzles that discharge the ink.

In such an apparatus, the unevenness of the recording color for each recording head block occurs due to the difference of properties of every recording head block. There is a demand for a technique for suppressing the unevenness of such recording color.

For example, a scheme that forms color profiles for each recording head block and corrects the unevenness of the recording color for each recording head block is considered. However, in this scheme, since a plurality of the color profiles that takes an extremely large number of man hours in forming and storing needs to be used, processing time, man hours for adjustment, costs and the like are increased.

### BRIEF DESCRIPTION OF THE DRAWINGS

FIG. 1 is a diagram illustrating one example of a layout of a drum and a plurality of recording head blocks which constitute a color recording portion of a color ink jet recording apparatus according to the embodiment.

FIG. 2 is a diagram illustrating one example of a recording head block according to the embodiment.

FIG. 3 is a diagram illustrating one example of a relationship of each color point position.

FIG. 4 is a diagram illustrating one example of the variation of a recording color according to position shift.

FIG. 5 is a diagram illustrating one example of a configuration of a correction processing portion according to the embodiment.

FIG. 6 is a diagram illustrating one example of CMYK color space.

FIG. 7 is a diagram for explaining the Jacobian matrix configured of four vectors ΔC, ΔM, ΔY, and ΔK.

FIG. 8 is a diagram illustrating an image forming apparatus (color correction processing apparatus) according to the embodiment.

FIG. 9 is a diagram illustrating one example of color patches of each head.

### DETAILED DESCRIPTION

In general, according to one embodiment, a color correction processing apparatus includes an input portion, a storing portion and a correction portion. The input portion inputs each image signal value corresponding to each color component for each recording head block in order to record a color image by a plurality of recording head blocks. The storing portion stores reference color deviation amount data that shows a plurality of reference color deviation amounts corresponding to a plurality of reference color points for each recording head block. The correction portion corrects each image signal value on the basis of the reference color deviation amount data. Furthermore, the correction portion corrects a correction target image signal value corresponding to a non-reference color point shifted from the reference color points by the interpolation on the basis of the reference color deviation amount data.

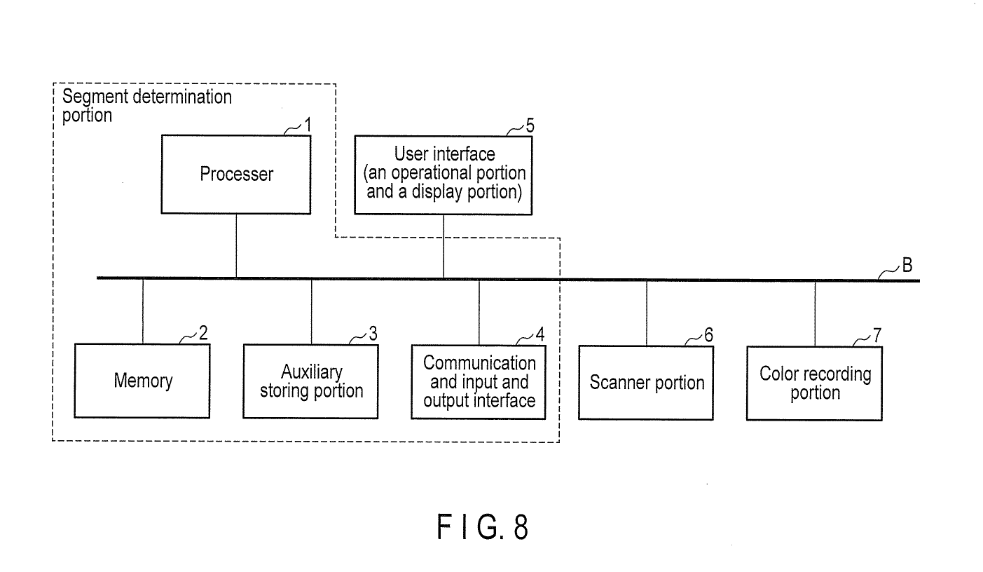

FIG. 8 is a diagram illustrating one example of an image forming apparatus (a color correction processing apparatus) according to the embodiment. The image forming apparatus shown in FIG. 8 includes a processor 1, a memory 2, an auxiliary storing portion 3, a communication and input and output interface 4, a user interface (an operational portion and a display portion) 5, a scanner portion 6 and a color recording portion 7. The processor 1, the memory 2, the auxiliary storing portion 3, the communication and input and output interface 4, the user interface (the operational portion and the display portion) 5, the scanner portion 6 and the color recording portion 7 are connected with each other by data and control signal bus.

A color correction processing that will be described in the embodiment can be realized by, for example, the processor 1, the memory 2, the auxiliary storing portion 3 and the communication and input and output interface (I/F) 4. The processor 1 functions as a correction portion, at least one of the memory 2 and the auxiliary storing portion 3 functions as the storing portion and the communication and input and output interface (I/F) 4 functions as the input portion.

Here, in the present embodiment, the color correction processing by the image forming apparatus will be described; however, the color correction processing described in the embodiment can be realized by a separated printer server or the like from the image forming apparatus and by a computer which provides image data of a color correction processing target as well.

(Concept of Color Recording Portion 7)

The color correction processing according to the color ink jet recording apparatus (the image forming apparatus shown in FIG. 8) will be described.

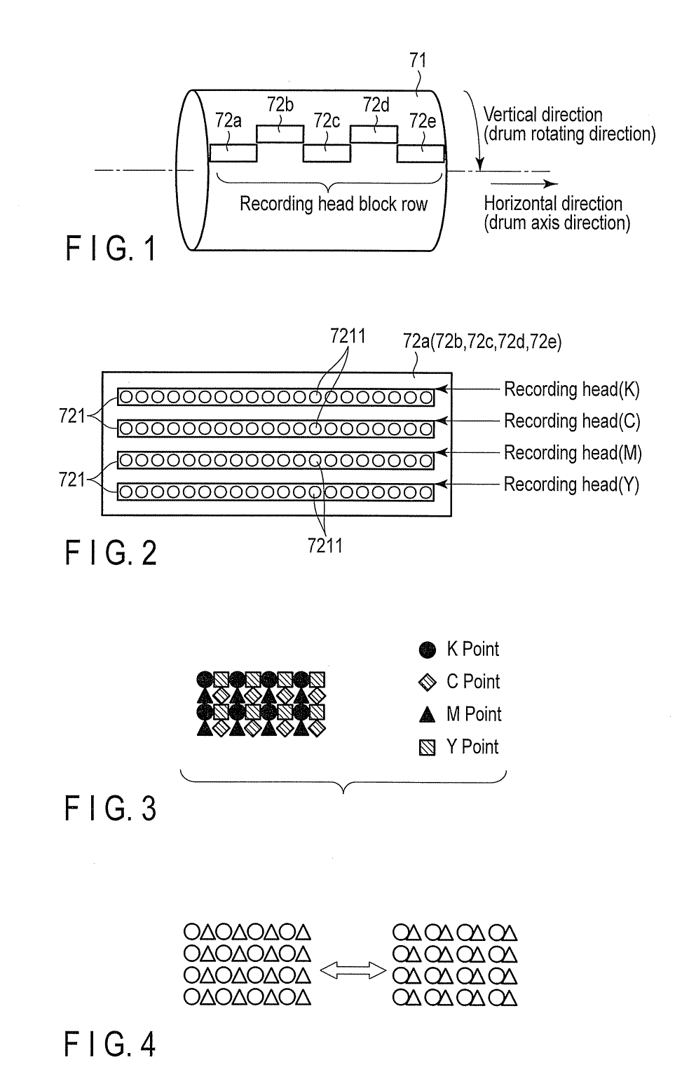

FIG. 1 is a diagram illustrating one example of a layout of a drum and a plurality of recording head blocks that constitute the color recording portion 7 of the color ink jet recording apparatus.

As shown in FIG. 1, the color recording portion 7 includes a drum 71 that affixes and rotates paper sheets to be printed, a recording head block row facing the drum and a driving system, a paper sheet combining/discharging system and a signal processing system of the drum.

The recording head block row is configured so as to juxtapose a plurality of recording head blocks 72a, 72b, 72c, 72d, and 72e in the horizontal direction (in the axial direction of the drum). The recording head blocks 72a, 72b, 72c, 72d, and 72e are disposed in a zigzag state in order to avoid the overlapping of each end portion of the recording head blocks 72a, 72b, 72c, 72d, and 72e.

As shown in FIG. 2, each of the recording head blocks 72a, 72b, 72c, 72d, and 72e includes a plurality of the recording heads (nozzle plates) 721 that discharge inks (each color component) of four CMYK colors respectively. Each recording head 721 is juxtaposed in the vertical direction (in the rotational direction of the drum).

In addition, each recording head 721 is configured by the array of a plurality of ink discharging nozzles 7211 that discharge each color ink. The color recording portion 7 controls the discharged amount of the ink from the ink discharging nozzles 7211 of each recording head 721 in response to the image signal (image signal value) while rotating the drum 71 to which the paper sheet is affixed. Therefore, the color recording portion 7 forms an image of gray distribution in response to the image signal on the paper sheet.

In the following explanations, the recording head blocks 72a, 72b, 72c, 72d, and 72e may be only recorded as the head.

In order to form a color image, relative positions between each of the head 721 are set so that points of the four inks have a predetermined position relation and a discharging timing of the ink from the ink discharging nozzles 7211 is set.

For example, as shown in FIG. 3, the four color inks are set so as to be discharged in different positions from each other. In color recording, even when the discharged amounts of the four color ink are identical, when the relative positions of each ink vary, the chromaticity of the recorded color also varies.

FIG. 4 is a diagram illustrating one example of the variation of the recording color by the position deviation to be printed. The position to be printed between the ink colors relies on the accuracy of the affixed position that of the recording heads 721 and the variation in the discharge direction of the ink from the recording heads 721. For this reason, there are some cases where variation occurs in the relative positions to be printed of each ink for each recording head block 72a, 72b, 72c, 72d, and 72e and therefore, unevenness of the chromaticity may occur in each recording region by the recording head blocks 72a, 72b, 72c, 72d, and 72e.

(Color Correction Processing)

By color correction processing which will be described hereinafter, it is possible to provide color recording capable of correcting color unevenness that is stable and has no unevenness. The color correction processing according to the embodiment can be realized in a relatively smaller scale from the viewpoint as below.

1. A chromaticity deviation amount of an arbitrary point is obtained from the chromaticity deviation amount of a limited number of reference points. In other words, the deviation amount of the chromaticity of the arbitrary point is estimated from the deviation amount of the chromaticity of the reference points.

2. A CMYK correction amount is calculated using the Jacobian matrix from the color deviation amount. Hereinafter, the above 1 and 2 will be described.

In the present embodiment, the deviation of the chromaticity of each recording head 721 is measured in advance due to the relative deviation of the position to be printed between the ink colors. Since the image signal is a 8-bit signal for CMYK respectively, total combined color signal becomes 32nd power of 2; therefore, it is difficult to realize the measurements of the deviation amount of all the combined color signal. Meanwhile, the deviation of the chromaticity is remarkable when the image signal value is in the median value and when the value is 0 or 255, since the ink point is substantially constant, the deviation of the chromaticity becomes 0 or extremely small. For this reason, when the image signal value of CMYK (CMYK signal value) is in the median value, a number of points of the reference points are determined and the color deviation amounts of the reference points are measured in advance. The color deviation amounts of the signals (signals shifted from the reference points) except for the reference points are estimated by the interpolation from the values of the reference points (two or more reference points). However, for the convenience for the calculation of the interpolation, the reference points are disposed even on the outer most surface (on the surface where any one of C, M, Y, and K becomes 0 or 1) in the color signal space.

Next, the correction (increase and decrease) amount of the CMYK signal value is calculated using the Jacobian matrix for correcting color deviation Δ Lab by the color deviation Δ Lab calculated by the explanation described above. The Jacobian matrix is a matrix that shows a relationship of the fine change of the CMYK signal value and the fine change of the Lab chromaticity value. The changed amount (this may be estimate) of the chromaticity Lab of the reproduction color with respect to the fine change of the CMYK signal value is calculated and a inverse matrix is calculated, thereby the correction amount can be easily obtained. However, since the Lab is three dimensional while the CMYK signal existing in the four dimensional space, it is necessary to determine the restriction conditions between the CMYK and use the restriction conditions in the inverse matrix calculating.

(Detailed Explanation of Color Correction Processing)

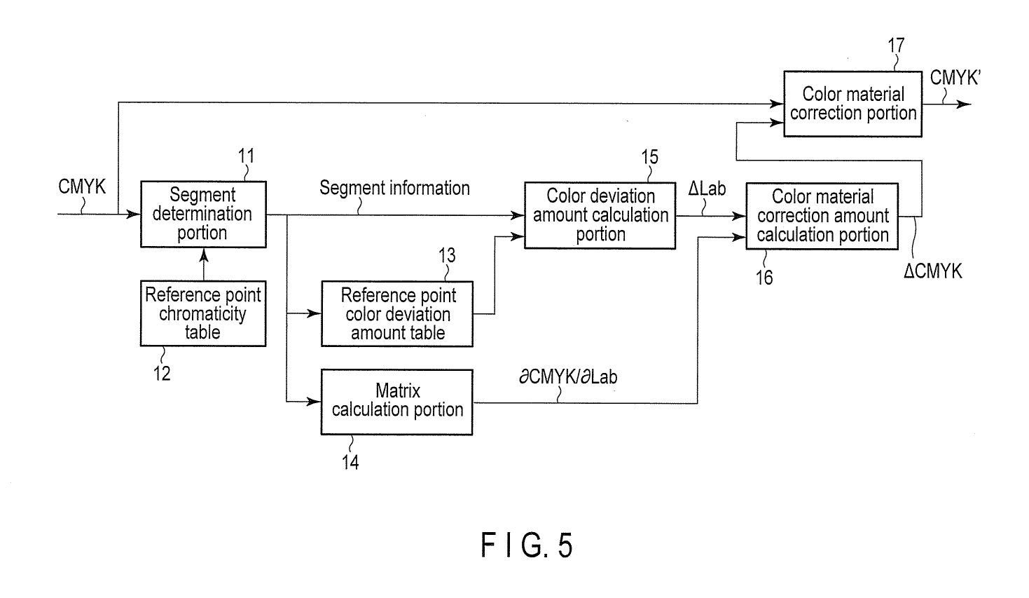

Next, the sequence of the correction processing portion (the processor 1, the memory 2, the auxiliary storing portion 3, and the communication and input and output interface 4) and the calculation will be described in detail. A configuration of the correction processing portion is shown in FIG. 5. The correction processing portion shown in FIG. 5 can be realized by, for example, software of the processor 1, the memory 2, the auxiliary storing portion 3, the communication and input and output interface 4 and the like.

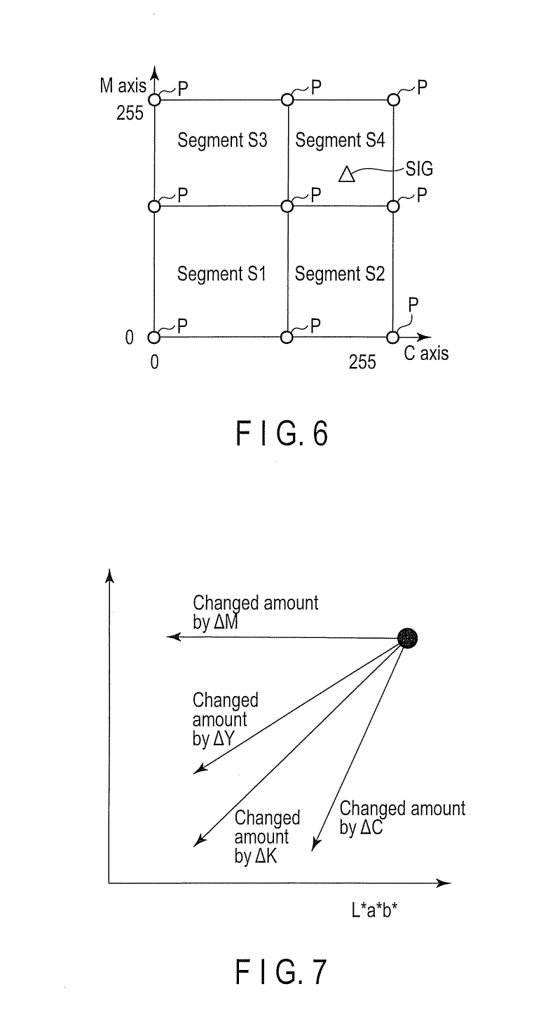

First, a segment determination portion 11 calculates segment information S and a heavy signal W by the input CMYK signal and an existing reference chromaticity table 12. The segment determination portion 11 determines the segment by a plurality of reference points P that surround the input CMYK signal value near the input CMYK signal value. The segment is a partial space, discriminated by the reference color in the CMYK color space. FIG. 6 is a diagram illustrating one example of the CMYK color space. In FIG. 6, for example, segments S1 to S4 which are included in the CMYK color space are shown. In addition, the CMYK color space was originally a four dimensional space; however, since the four dimensional space is difficult to be illustrated in the drawings, a two dimensional space is illustrated in FIG. 6 for the convenience for the explanation. For example, an input CMYK signal SIG belongs to the segment S4. The segment determination portion 11 outputs the segment information S that shows the four reference points P which surround the segment S4 and the heavy signal Wᵢ that shows the four reference point contribution to the segment.

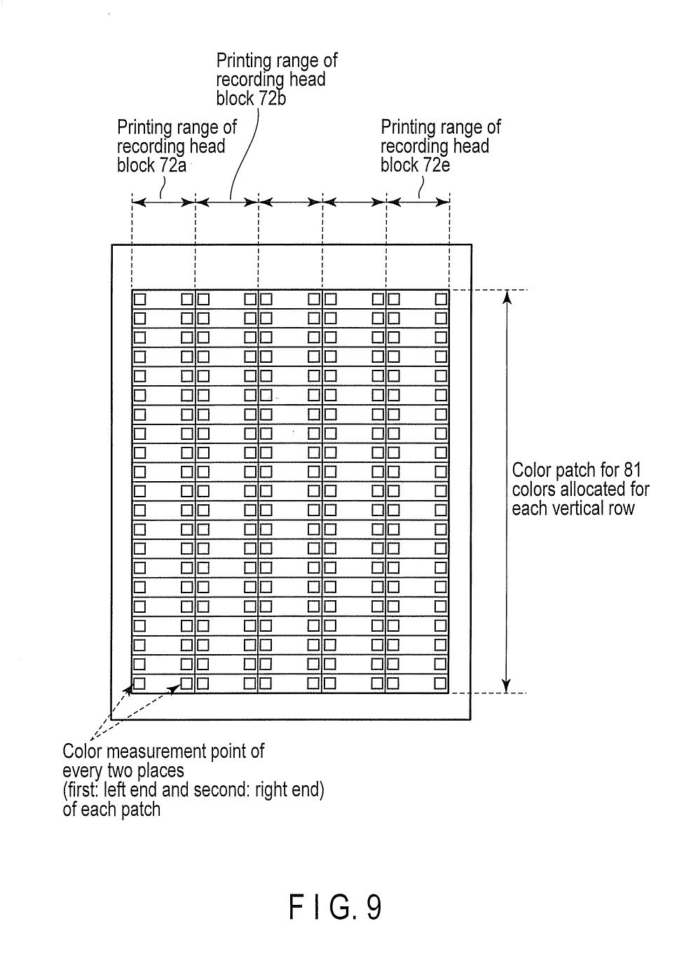

Next, the reference point color deviation amount table 13 outputs a reference point color deviation amount Δ Labᵢ regarding respective plural reference points of the segment information S. The reference point color deviation amount table 13 stores the color deviation amounts of arbitrary recording heads with respect to the CMYK value of the reference points. That is, the reference point color deviation amount table 13 contains the difference from the color value that is stored in standard recording heads (reference recording heads) with respect to the CMYK value of the reference points. For that reason, the color patches are recorded in each head in advance (refer to FIG. 9), the color of the color patches (recording results) of each head are measured and the values (color deviation amount) calculated based on the measured results are stored in the reference point color deviation amount table 13.

Next, a color deviation amount calculation portion 15 calculates the color deviation amount Δ Lab. In other words, the color deviation amount calculation portion 15 calculates the sum of products of the color deviation amount in a plurality of reference points output from the reference point color deviation amount table 13 and the heavy signal W of each reference point.

Δ Lab shows an estimated value of the color deviation amount in pixels of the input CMYK signal. Δ Lab is expressed by Equation (1) as below.

$$ΔLab = {\sum }_{i} Δ {Lab}_{i} \cdot {W}_{i} \qquad ( 1 )$$

Next, a matrix calculation portion 14 calculates and outputs a correction matrix ∂ CMYK/∂ Lab in each reference point of the segments. This correction matrix is the Jacobian matrix that shows the relationship of the deviation amount of the Lab and the changed amount of the CMYK. A detailed description regarding a calculation method will be made. The matrix calculation portion 14 stores the value of the Jacobian matrix ∂ Lab/∂ CMYK that show the variation of the reproduction chromaticity Lab with respect to the fine change of the CMYK in each reference color. The value of the Jacobian matrix ∂ Lab/∂ CMYK is a fixed value regardless of the recording heads 721. The value of the Jacobian matrix ∂ Lab/∂ CMYK can be obtained by measuring the chromaticity Lab of the color recorded by changing the CMYK by ΔC, ΔM, ΔY, and ΔK of the very small amounts from the CMYK and calculating the difference of chromaticities between the obtained and the recorded colors in the CMYK. The Jacobian matrix is a matrix configured of four vectors ΔC, ΔM, ΔY, and ΔK shown in FIG. 7.

On the other hand, the matrix calculation portion 14 stores parameters Ac, Am, and Ay that show the relationship of the CMYK of each reference point. The restriction relationship Equation (2) is as below.

$$\begin{matrix}Δ K = Ac \times Δ C + Am [ Δ M + Ay \times Δ Y \\ If restriction matrix A is indicated as \\ restriction matrixA = [ \begin{matrix}1 & 0 & 0 \\ 0 & 1 & 0 \\ 0 & 0 & 1 \\ Ac & Am & Ay\end{matrix} ] \\ the below formulae are satisfied , \\ ΔLab = \partial Lab / \partial C M Y K \cdot A \cdot Δ C M Y , \\ Δ C M Y = inv ( \partial Lab / \partial C M Y K \cdot A ) ΔLab , and \\ Δ C M Y K = A \cdot inv ( \partial Lab / \partial C M Y K \cdot A ) ΔLab \\ however , inv ( X ) indicates the reverse matrix of matrix X . \\ That is , favorably , the below formula may be calculated . \\ \partial C M Y K / \partial Lab = A \cdot inv ( \partial Lab / \partial C M Y K \cdot A )\end{matrix} \} \qquad ( 2 )$$

In other words, Equation (3) may be calculated.

∂CMYK/∂Lab=A·inv(∂Lab/∂CMYKA) (3)

Since this matrix does not depend on in the parameters such as the recording heads, the matrix is calculated in advance and the matrix calculation portion 14 stores the matrix.

Next, a color material correction amount calculation portion 16 calculates a color material correction amount Δ CMYK by the color deviation amount Δ Lab and the Jacobian matrix ∂ CMYK/∂ Lab in each reference color. The color material correction amount calculation portion 16 multiplies the Δ Lab to the product of the Jacobian matrix and the heavy signal W of each reference color and adds the multiplied values to each other. The calculated Δ CMYK shows the CMYK correction amount to be added to the CMYK signal for correcting the variation of the reproduction chromaticity by the color deviation of the recording heads 721. The Δ CMYK is shown in Equation (4) as below.

$$Δ C M Y K = {\sum }_{i} ( {W}_{i} \cdot \partial C M Y K / \partial {Lab}_{i} ) \cdot ΔLab \qquad ( 4 )$$

Finally, a color material correction portion 17 subtracts the Δ CMYK, the CMYK correction amount, from the input CMYK signal and outputs the correction CMYK signal (CMYK′). The CMYK′ is shown in Equation (5) as below.

CMYK′=CMYK−ΔCMYK (5)

By the series of processing described above, the correction processing portion (color material correction portion 17) outputs the correction CMYK signal (CMYK′) that the influence of the color deviation of the head is corrected. The color recording portion 7 controls the discharging amount of the ink from the ink discharging nozzles 7211 of each of the recording heads 721 on the basis of the correction CMYK signal (CMYK′). This can realize color recording in which the color variation for each recording head block is corrected.

According to each color correction processing of the embodiment described above, it is possible to correct the deviation of the chromaticity of the recording image caused by the deviation of the position to be printed between the recording head blocks. Furthermore, according to the color correction processing of the embodiment above, it is possible to suppress the measurement of the head property and the storing capacity of the property data to be reduced using the color deviation of the reference points and the Jacobian matrix of the CMYK signal and the chromaticity.

Outlines of the present embodiments are as below.

1. There is a deviation amount table of chromaticity of reference points of larger deviation on the color space as a table.
2. The Jacobian matrix (∂ CMYK/∂ Lab) of the increased amount of CMYK and the chromaticity deviation are stored at each reference point.

3. The relation equation (restriction condition) between the CMYK signals of the each reference point is stored in the table.

4. By the chromaticity deviation of the each reference point, the Jacobian matrix and the relation equation between the signals, the correction amounts of the CMYK signals are calculated.

5. The interpolation of each reference point correction amount is used except for the reference points.

6. As the reference points, any one of the outer most points (points of solid color=(C, M, Y, and K are all 0% or 100%) and points for which a specific ink amount is selected and outside of that the solid color is selected (a point having the largest influence on the chromaticity due to the position deviation).

In addition, Δ Lab is shown in Equation (6) as below.

$$ΔLab is vector [ \begin{matrix}Δ {L}^{*} \\ Δ {a}^{*} \\ Δ {b}^{*}\end{matrix} ] \qquad ( 6 )$$

In addition, Δ CMYK is shown in Equation (7) as below.

$$ΔC M Y K is vector [ \begin{matrix}Δ C \\ Δ M \\ Δ Y \\ Δ K\end{matrix} ] \qquad ( 7 )$$

In addition, ∂ Lab/∂ CMYK are shown in Equation (8) as below.

$$\partial Lab / \partial C M Y K is Jacobian matrix [ \begin{matrix}\partial {L}^{*} / \partial C & \partial {L}^{*} / \partial M & \partial {L}^{*} / \partial Y & \partial {L}^{*} / \partial K \\ \partial {a}^{*} / \partial C & \partial {a}^{*} / \partial M & \partial {a}^{*} / \partial Y & \partial {a}^{*} / \partial K \\ \partial {b}^{*} / \partial C & \partial {b}^{*} / \partial M & \partial {b}^{*} / \partial Y & \partial {b}^{*} / \partial K\end{matrix} ] \qquad ( 8 )$$

In addition, ∂ CMYK/∂ Lab is shown in the equation (9) as below.

$$\partial C M Y K / \partial Lab is Jacobian matrix [ \begin{matrix}\partial C / \partial {L}^{*} & \partial C / \partial {a}^{*} & \partial C / \partial {b}^{*} \\ \partial M / \partial {L}^{*} & \partial M / \partial {a}^{*} & \partial M / \partial {b}^{*} \\ \partial Y / \partial {L}^{*} & \partial Y / \partial {a}^{*} & \partial Y / \partial {b}^{*} \\ \partial K / \partial {L}^{*} & \partial K / \partial {a}^{*} & \partial K / \partial {b}^{*}\end{matrix} ] \qquad ( 9 )$$

In the above-described embodiments, the case in which the image forming apparatus performs color correction processing was described, the embodiment is not limited thereto. Same functions (color correction processing program) may be downloaded to the apparatus from a network. In addition, a storing medium in which the same function (color correction processing program) is stored may be installed to the apparatus. Any medium which can store programs and can be read by the apparatus, such as CD-ROM and DVD, may be used as the storing medium. As described above, the function obtained by installing or downloading in advance may be realized by cooperating with OS (operating system) or the like of the apparatus.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A color correction processing apparatus comprising:
an input portion that inputs each image signal value corresponding to each color component for each recording head block in order to record a color image by a plurality of recording head blocks;
a storing portion that stores reference color deviation amount data which indicates a plurality of reference color deviation amounts corresponding to a plurality of reference color points for each recording head block; and
a correction portion that corrects the respective image signal value on the basis of the reference color deviation amount data, and corrects a correction target image signal value corresponding to non-reference color points shifted from the reference color points by the interpolation on the basis of the reference color deviation amount data.

2. The apparatus according to claim 1,
wherein the correction portion estimates—color deviation amounts of the non-reference color points shifted from the reference color points by the interpolation on the basis of the reference color deviation amount data and corrects the correction target image signal value on the basis of the estimated color deviation amounts.

3. The apparatus according to claim 1,
wherein the correction portion detects a segment to which the correction target image signal value belongs among the plurality of the segments in a color space, which is configured of a plurality of segments, including the reference color points and corrects the correction target image signal value which belongs to the detected segment by the interpolation on the basis of the data which shows two or more reference color deviation amounts corresponding to two or more reference color points that constitute the detected segment.

4. The apparatus according to claim 3,
wherein the correction portion estimates the color deviation amount of the correction target image signal value which belongs to the detected segment on the basis of the data that shows the two or more reference color deviation amounts corresponding to the two or more reference color points which constitutes the detected segment and corrects the correction target image signal value on the basis of the estimated color deviation amount.

5. The apparatus according to claim 1,
wherein the storing portion stores a reference matrix that shows a relationship of the color deviation amount and a color material correction amount in each of the reference color points and
wherein the correction portion estimates the color material correction amount corresponding to the correction target image signal value on the basis of the reference matrix and corrects the correction target image signal value on the basis of the estimated color material correction amount.

6. The apparatus according to claim 5,
wherein the correction portion calculates a correction matrix that shows a relationship of the color deviation amount and the color material correction amount of the correction target image signal value, estimates the color material correction amount corresponding to the correction target image signal value on the basis of the correction matrix and corrects the correction target image signal value on the basis of the estimated color material correction amount.

7. The apparatus according to claim 1,
wherein the input portion inputs each CMYK signal value corresponding to each color component for each recording head block and
wherein the correction portion corrects correction target CMYK signal values corresponding to the non-reference color points shifted from the reference color points by the interpolation on the basis of the reference color deviation amount data.

8. The apparatus according to claim 7,
wherein the correction portion estimates Δ Lab corresponding to the color deviation amounts of the correction target CMYK signal values that correspond to the non-reference color points shifted from the reference color points by the interpolation on the basis of the reference color deviation amount data and corrects the correction target image signal value on the basis of the estimated Δ Lab.

9. The apparatus according to claim 8,
wherein the storing portion stores a reference matrix that shows a relationship of the color deviation amount and a color material correction amount in each reference color points and
wherein the correction portion estimates the color material correction amount Δ CMYK from the estimated Δ Lab on the basis of the reference matrix and corrects the correction target CMYK signal values on the basis of the estimated color material correction amount Δ CMYK.

10. The apparatus according to claim 9,
wherein the correction portion calculates a correction matrix that shows a relationship of the color deviation amount and the color material correction amount of the correction target CMYK signal value, estimates the color material correction amount Δ CMYK on the basis of the correction matrix corresponding to the correction target CMYK signal values on the basis of the correction matrix and corrects the correction target CMYK signal value on the basis of the estimated color material correction amount Δ CMYK.

11. An image forming apparatus configured of the apparatus according to claim 1, comprising:
a plurality of the recording head blocks,
wherein the plurality of recording head blocks records a color image on the basis of each image signal value corresponding to each color component for each recording head block including the corrected correction target image signal value.

12. A color correction processing method comprising:
correcting each image signal value corresponding to each color component for each recording head block in order to record a color image by the recording head blocks on the basis of reference color deviation amount data that shows a plurality of reference color deviation amounts corresponding to a plurality of reference color points for the respective recording head block; and
correcting a correction target image signal value corresponding to non-reference color points shifted from the reference color points by the interpolation on the basis of the reference color deviation amount data.

13. The method according to claim 12, comprising:
estimating color deviation amounts of the non-reference color points shifted from the reference color points by the interpolation on the basis of the reference color deviation amount data and correcting the correction target image signal value on the basis of the estimated color deviation amounts.

14. The method according to claim 12, comprising:
detecting a segment to which the correction target image signal value belongs among the plurality of the segments in a color space, which is configured of a plurality of segments, including the reference color points and correcting the correction target image signal value which belongs to the detected segment by the interpolation on the basis of the data which shows two or more reference color deviation amounts corresponding to two or more reference color points that constitute the detected segment.

15. The method according to claim 12, comprising:
estimating the color material correction amount corresponding to the correction target image signal value on the basis of a reference matrix that shows a relationship of the color deviation amount and a color material correction amount in each of the reference color points and correcting the correction target image signal value on the basis of the estimated color material correction amount.

16. The method according to claim 12, comprising:
inputting each CMYK signal value corresponding to each color component for each recording head block; and
correcting correction target CMYK signal values corresponding to the non-reference color points shifted from the reference color points by the interpolation on the basis of the reference color deviation amount data.

17. The method according to claim 12, comprising:
recording a color image on the basis of each image signal value corresponding to each color component for each recording head block including the corrected correction target image signal value.
